(19) United States
(12) Patent Application Publication
(10) Pub. No.: US 2025/0149363 A1
(43) Pub. Date: May 8, 2025

(54) METHODS AND APPARATUS FOR PURIFYING SUBSTRATE CONTAINERS

(71) Applicant: ENTEGRIS, INC., Billerica, MA (US)

(72) Inventors: Matthew A. Fuller, Colorado Springs, CO (US); Colton J. Harr, Monument, CO (US); Paul J. Magoon, Colorado Springs, CO (US); Rocky Dean Gipson, Arroyo Grande, CA (US); Gary Gallagher, Austin, TX (US)

(21) Appl. No.: 18/935,313

(22) Filed: Nov. 1, 2024

Related U.S. Application Data
(60) Provisional application No. 63/547,292, filed on Nov. 3, 2023.

(51) Int. Cl. H01L 21/673; H01L 21/67

(52) U.S. Cl. CPC H01L 21/67393; H01L 21/67288

(57) ABSTRACT

Described are methods and apparatus that are useful to for purifying a substrate container that is used to hold, store, or transport semiconductor substrates.

### FIELD

The invention relates to methods and apparatus that are useful for purifying a substrate container that is used to hold, store, or transport semiconductor substrates.

### BACKGROUND

During semiconductor and microelectronic device manufacturing, semiconductor substrates are processed to form microelectronic devices by performing a lengthy series of processing steps at a surface of the substrate. The steps include cleaning, material deposition, chemical processing such as photolithography, material removal such as by planarization or etching, among others, performed repeatedly over a course of producing a finished microelectronic device. The presence of contaminants at the substrate surface during any of these processing steps or between processing steps will produce defects within microelectronic devices being formed on the substrate and will reduce yield.

To reduce the presence of contamination at substrate surfaces, semiconductor substrates are processed in a highly controlled and purified atmosphere of a cleanroom. The cleanroom atmosphere is monitored and controlled to extremely high levels of purity in terms of particle contaminants and chemical contaminants sometimes referred to as “airborne molecular contaminants”). Even with the best current technologies, cleanrooms still contain very low levels of contaminants, e.g., airborne molecular contaminants and particle contaminants. The airborne molecular contaminants include airborne chemical species such as volatile chemical compounds that may be inorganic (common examples being acid or base molecules such as ammonia (NH₃)) or organic (common examples including organic solvents such as isopropanol and acetones). To reduce the presence of these contaminants, the cleanroom environment is continuously filtered and monitored.

Between processing steps, semiconductor substrates are conventionally stored or transported in a portable substrate container that holds the substrate in an enclosed container having a controlled atmosphere. The controlled atmosphere typically originates in a cleanroom that contains substrates. As the substrates are placed into the container, the cleanroom atmosphere also becomes enclosed at the container atmosphere. That cleanroom atmosphere contains very low levels of contaminants that become present in the gaseous atmosphere contained by the substrate container interior. Additionally, substrates that are placed from the cleanroom into the container interior have chemical materials present on surfaces of the substrates such as moisture, particles, or volatile chemical compounds. These materials may transfer from being present at the substrate surfaces to being present in the gaseous atmosphere of the container and may accumulate within the gaseous atmosphere.

At convenient or opportune times, a substrate container that contains a batch of substrates and a gaseous atmosphere that contains an accumulated level of contaminants may undergo a step of replacing the gaseous atmosphere with a fresh atmosphere. This process of replacing a gaseous atmosphere at a container interior with a fresh gaseous atmosphere is referred to as a step of “purging” the atmosphere or the container, e.g., a “purge step.” Typical techniques of purging a substrate container may be effective to remove the gaseous atmosphere and contaminants that are present in the atmosphere and replace that atmosphere with a clean dry gas such as clean dry air or nitrogen, each having extremely low levels of chemical and particle contaminants. See for example U.S. Pat. No. 9,312,152 (L. Rebstock).

However, certain contaminants that may be present at a substrate container interior are not effectively removed using a purge step. Accordingly, different techniques and equipment can be useful to more thoroughly clean or to “purify” a substrate container in a manner that reduces the presence of contaminants to levels that are below levels of contaminants achieved by a purge step, or to remove contaminants that are different from those removed during a purge step. A more thorough “cleaning” or “purification” process may be performed on a substrate container less often than purge steps and may be performed at times between periods of using the substrate container to contain and transport wafers. A cleaning or purification process may not merely replace the gaseous atmosphere contained in a substrate container but may more thoroughly reduce the presence of contaminants at the container interior to amounts (concentrations) that are lower than those achieved using a purge step.

### SUMMARY

Current techniques for purging semiconductor substrate containers are effective to replace a gaseous atmosphere of a substrate container that contains contaminants and moisture with a fresh gaseous atmosphere that does not contain contaminants or moisture. See for example U.S. Pat. No. 9,312,152 (L. Rebstock).

However, contaminants may be present not only within the gaseous atmosphere of a substrate container interior but will also be present in a substrate container based on the manufacturing and use history of the container.

In addition to contaminants that are present in a gaseous atmosphere (e.g., from a cleanroom atmosphere or from a surface of a substrate) held within a substrate container, the substrate container structure itself may contain contaminants that are either residues of a manufacturing step or that have become deposited on or adsorbed within materials of a container structure during a period of use.

For example, substrate containers are made from polymeric materials that are prepared by reacting ingredients that include polymers, monomers, plasticizers, metal catalyst, etc. The polymeric material may contain residual amounts of these materials that are released slowly from the container material over time. These chemical molecules, once released into the container interior, become airborne molecular contaminants that are capable of depositing onto a surface of a substrate contained in a substrate container, with the potential of forming defects during subsequent processing.

Other contaminants that may be present at a substrate container interior—not just in a gaseous atmosphere held at the interior—may have accumulated at interior surfaces of the substrate container during use of the substrate container. When a substrate container is used to hold substrates, contaminants present in a container atmosphere will contact interior surfaces of the substrate container. These contaminants will accumulate at the interior surfaces by becoming deposited at the surface and also by diffusing into the surface and becoming adsorbed by the material of the surface.

Techniques of purging a substrate container have limited or variable effectiveness with respect to removing contaminants that are not merely present in a gaseous atmosphere of a substrate container, but that are present (adsorbed, deposited, or residual) at a surface of an interior structure of a substrate container. These contaminants remain present within a substrate container after a purging process at levels that are sufficiently high to allow the contaminants to become released into the container interior and deposited at a surface of a substrate held within the substrate container, where the contaminants may cause defects during processing, particularly with ever-smaller sizes of microelectronic device features.

Different from purging, the present description relates to techniques for more thoroughly cleaning or “purifying” a substrate container in a manner that: is effective to remove a greater amount of total contaminants present in a gaseous container atmosphere (e.g., the purifying step achieves a lower level of contaminants in the container atmosphere compared to a purge step); or that may be useful to remove a broader range or different types of airborne molecular contaminants from the container compared to a purge step; or that is effective to remove contaminants that are present at a surface of a substrate container interior, including either residual or accumulated contaminants that accumulate at a surface of or become adsorbed within a material of an interior structure such as a sidewall. Example purification step are effective to remove contaminants that are adsorbed in a sidewall structure by forcing the contaminants to diffuse out of the material and into the environment of the purification step.

Current techniques for cleaning substrate containers to a greater degree compared to a purge step may involve: static getters, a step of vacuum baking a container, or washing a container using significant volumes of highly purified water. These types of methods may undesirably consume significant amounts of purified water or purified nitrogen, require a significant amount of time, or both. Methods that take less time and that avoid the use of large volumes of water or nitrogen would be preferred.

In one aspect, the invention relates to a system for purifying a substrate container. The substrate container includes: a container body comprising an opening, a door adapted to cover the opening, an interior defined by the container body, and gas within the interior; the purification system comprising: a contaminant removal device in fluid communication with the interior, a sensor in fluid communication with the interior and adapted to detect airborne molecular contaminant in the gas, a control system adapted to measure a concentration of airborne molecular contaminant in the gas, and optionally to compare the concentration to a criteria concentration.

In another aspect, the invention relates to a method of purifying a substrate container. The method includes, in a substrate container comprising: a container body having an opening, a door adapted to cover the opening, an interior defined by the container body, and gas within the interior; causing the gas to contact a contaminant removal device to remove an airborne molecular contaminant from the gas, measuring a concentration of the airborne molecular contaminant in the gas, and comparing the concentration of airborne molecular contaminant in the gas to a predetermined criteria concentration.

In another aspect, the invention relates to a purification step for purifying a substrate container. The purification step includes stopping the purification step at a predetermined criteria concentration of an airborne molecular contaminant.

In yet another aspect the invention relates to a substrate container that includes a container body and a purification system. The substrate container includes: a container body having an opening, a door adapted to cover the opening, an interior defined by the container body, gas within the interior, and a purification system as a permanent or removable component of the substrate container. The purification system includes: a contaminant removal device in fluid communication with the interior, a sensor in fluid communication with the interior adapted to detect airborne molecular contaminant in the gas, and a control system adapted to measure a concentration of airborne molecular contaminant in the gas and to compare the concentration to a criteria concentration.

### BRIEF DESCRIPTION OF THE DRAWINGS

FIG. 1 is a perspective view of an example substrate container as described.

FIG. 2 is a schematic view of steps of an example purification method.

FIGS. 3A and 3B are side cut-away views of example substrate containers and purification systems.

FIG. 3C is a front cut-away view example of substrate containers and purification systems.

FIGS. 4A and 4B are side cut-away views of an example substrate container, purification system, and method.

FIG. 5 is a side cut-away view of an example substrate container and purification system as part of a load port.

All figures are schematic and not to scale.

### DETAILED DESCRIPTION

Described as follows are substrate container purification systems and methods that are effective to remove various contaminants from a substrate container and to reduce the level of those contaminants to quantitatively-determined amounts.

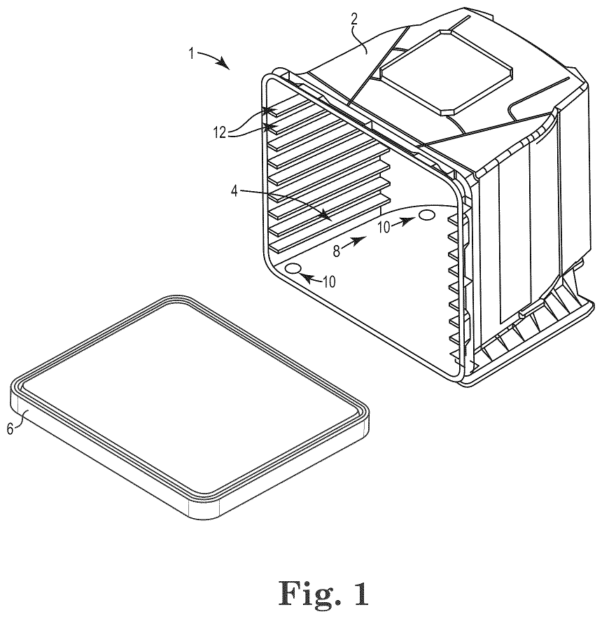

A substrate container (or simply a “container” as used herein) includes a container body that has an interior, an opening on one side of the body to access the interior, and a door that is adapted to selectively cover and seal the opening. The container will typically also include one or more inlet ports to allow gas to be added to the interior and one or more outlet ports to allow gas to be removed from the interior, such as for purging the interior atmosphere with a purge gas. One example of a substrate container is shown at FIG. 1, discussed below.

According to the description, a purification system can be used with the substrate container to purify the container by removing contaminants from the substrate container interior. The purification system may include a contaminant removal device in fluid communication with the interior, which may be or may comprise an adsorbent, catalytic oxidizer, or similar device that is effective to remove an airborne molecular contaminant from a gas by contacting the gas, and an optional filter to remove particle contamination from the gas by contacting the gas. The purification system may also contain a sensor in fluid communication with the container interior to measure a concentration of one or more different airborne-molecular contaminants that are present in a gas contained in the interior or flowing out of the interior. The purification system may also include a control system adapted to analyze the concentration of one or more contaminants present in the gas.

Example purification systems can be useful to purify a substrate container by passing a gas (e.g., a gaseous atmosphere or a purifier gas) that is contained within or that flows from the substrate container interior through a contaminant removal device while monitoring a concentration of a contaminant in the gas. The gas may be a gaseous atmosphere contained in the substrate container interior, or the gaseous atmosphere combined with a purifier gas, or a purifier gas that displaces the gaseous atmosphere and then circulates or re-circulates within the container interior. The gas (gaseous atmosphere, purifier gas, or a mixture of these) may be circulated once or multiple times (recirculated) through the interior and through the purification system during a purification step until a desired low (maximum) concentration of one or more airborne molecular contaminants is measured as being present in the gas.

Example purification systems can include specific types of contaminant removal devices that are effective to remove various general and specific types of contaminants from a substrate container interior. In particular, the device can be used to reduce a level (concentration) of one or more airborne molecular contaminants to desirably low concentrations that are lower than concentrations of these contaminants achieved by conventional purge systems or substrate or substrate container washing systems.

A substrate container may contain contaminants of various types derived from multiple sources. As one type of contaminant, the container structure itself is prepared from materials, e.g., polymeric materials such as plastics, that contain chemicals that form the container structure. These polymeric materials may contain small amounts of residual low molecular weight chemical molecules such as unreacted monomers, oligomers, solvents, plasticizers, or metal catalyst. These low molecular weight molecules are released from the container structure over time and become airborne molecular contaminants at the container interior. These molecules, derived from the structure of the container, may be referred to as “resident contaminants.”

Examples of resident contaminants include organic or inorganic chemical molecules such as unreacted monomers of a polymeric material of the structure, dimers or oligomers, plasticizers, organic solvents, and metal ions and metal-containing compounds used as catalysts, among others. Particular chemical species may include polycarbonates, reactive but unreacted monomers or oligomers, methyl-ethyl ketone (MEK), isopropyl alcohol (IPA), sulfur dioxide (SO₂), acetone, propylene glycol methyl ether acetate (PGMEA), aromatic compounds such as (toluene), aliphatic hydrocarbon molecules, alcohols, ammonia (NH₃), as well as other relatively low non-polymeric chemical constituents of a container structure that are used for preparing the structure but are non-polymeric materials that are capable of evolving from the structure over time. Purification systems and methods as described can be effective to remove these types of resident contaminants from a container interior and reduce a concentration of one or more of these resident contaminants to a desirably low concentration within the container interior during a purification step. In particular examples, a purification method can be effective to reduce a concentration of any one or more of these contaminants in a container interior (based on measuring a concentration in a gas within the container interior or flowing out of the container interior) to below a concentration of 0.5 parts per billion (ppb), or below 0.2 parts per billion, or below 100 parts per trillion (ppt).

Other contaminants, referred to as “exogenous contaminants,” are not resident contaminants derived from a container structure but are introduced into a substrate container from an exogenous source. An exogenous contaminant may be a chemical species that is present in a cleanroom atmosphere and becomes present within a container atmosphere while the container is connected to the cleanroom atmosphere, such as when placing substrates into the container. An exogenous contaminant may also be present at a surface of a semiconductor wafer that is placed within a substrate container and may be introduced into a gaseous container atmosphere from a surface of a wafer.

During use of a substrate container, exogenous contaminants may accumulate at interior surfaces of the substrate container. These exogenous contaminants will accumulate at the interior surfaces by becoming deposited at the surface and will also accumulate at the surface by diffusing into the surface and becoming adsorbed by the material of the surface. The amount of contaminant that diffuses into and is adsorbed by the material can depend on permeation characteristics of the material of the container structure (e.g., a polymeric sidewall) and the contaminant. A contaminant diffuses into (is adsorbed by) the bulk material of a polymeric sidewall at a given rate, and the amount of the contaminant that becomes adsorbed by the polymeric sidewall will depend on factors such as the solubility of the contaminant in the material of the sidewall.

Examples of exogenous contaminants include both particle contaminants and airborne molecular contaminants such as organic or inorganic molecules. Specific examples include organic and inorganic molecules that may be used as a solvent, a base, or an acid during semiconductor processing. More specific examples include organic and inorganic acid molecules; base molecules; amine compounds such as organic amines and silyl amines, organic compounds such as alcohols (isopropyl alcohol), acetones, and other low molecular weight organic solvents; ammonia (NH₃); sulfur dioxide (SO₂); ethyl acetate (EA); hydrogen fluoride (HF); methyl-ethyl ketone (MEK); propylene glycol monomethyl ether (PGME); propylene glycol methyl ether acetate (PGMEA); aromatic hydrocarbons such as toluene; as well as others. Purification systems and methods as described can be effective to remove these types of non-resident or “exogenous” contaminants from a container and to reduce the concentration of these contaminants to a desirably low concentration within a container during a purification step, including by removing exogenous contaminants that are deposited on surfaces of the container interior or adsorbed by a material of a container interior. In particular examples, a purification method can be effective to reduce a concentration of any one or more of these exogenous contaminants in a gaseous atmosphere of a substrate container to a measured concentration below 0.5 parts per billion (ppb), or below 0.2 parts per billion, or below 100 parts per trillion (ppt).

Example purification systems include a contaminant removal device in fluid communication with the container interior that is effective to remove one or more contaminants from the atmosphere by contacting the atmosphere with the contaminant removal device. A contaminant removal device can by any type of material or device that is effective to contact a contaminant that is contained (e.g., suspended) in a gas that is contained in or flows from the container interior and remove the contaminant from the gas. Examples include adsorbents, oxidizers (thermal oxidizers, catalytic oxidizers), and filters. In some examples, the contaminant removal device may include adsorbent that can be effectively regenerated, such as by exposing the adsorbent to elevated temperature to remove adsorbed contaminants.

A contaminant removal device for use in a purification system can be generally useful for removing one or more different contaminants (airborne molecular contaminants) from a flow of a gas, including contaminants that are typically present in cleanroom atmospheres. Useful examples of general classes and types of adsorbents used as a contaminant removal device include activated carbons, metal organic frameworks (MOF), zeolites such as zeolite imidazole frameworks (ZIFs), ion exchange resins, silicas, molecular sieves, and other adsorbent materials that are useful to adsorb airborne molecular contaminants. Many varieties of each of these types of adsorbents are known and commercially available.

For limited the purpose of naming useful examples, the following adsorbents can be identified. For removing moisture, a 3A zeolite (e.g., potassium A, or K-LTA) adsorbent may be useful. For relatively high levels of moisture (1000 ppm or greater), a silica gel bead may be useful due to its higher capacity. An activated carbon may be useful to remove volatile organic compounds. Examples of adsorbents that are useful for adsorbing organic compounds, moisture, and certain types of acids and bases include those types referred to as “13X” molecular sieves on the faujasite (FAU) structure, and zeolites such as those referred to as Li-LSX zeolite. A zeolite can be used after an activation step, for example by exposing the zeolite to high purity (7N) nitrogen at an elevated temperature (e.g., 300 degrees Celsius).

Certain airborne molecular contaminants may be difficult to remove from a substrate container to desirably-low concentrations using chemical adsorbent. These may include isopropyl alcohol, acetone, and ammonia (NH₂). According to example systems and methods of the present description, a purification system may include a thermal oxidizer or a catalytic oxidizer to remove these and other types of difficult-to-remove contaminants from a substrate container.

Example purification systems and components of a purification system can be arranged in any manner that allows a gas that is contained in or circulated or re-circulated through a substrate container to be brought to contact a contaminant removal device of the purification system, to effectively remove one or more contaminants from the gas.

According to example systems and containers, the system or one or more components of the system can be incorporated into a structure of a substrate container as part of the container, e.g., within the container interior or within a wall structure or a housing structure of the container structure. According to other example systems and containers, the system or one or more components of the system can be external to the container and a container housing and may be connected, e.g., removably connected, to the container in a manner to allow the gas to be caused to contact a contaminant removal device of the purification system.

Any such example purification system can be structured to form a closed fluid path between the substrate container interior and the contaminant removal device to allow a gas within the container to flow from the container interior, pass in contact with the contaminant removal device, and then (optionally) pass from the contaminant removal device and return to the container interior; i.e., the gas may optionally be circulated (or “recirculated”) between the container interior and the particle removal device. The gas may be a gaseous atmosphere contained in the closed substrate container passed through the purification device, or alternately a mixture of the gaseous atmosphere combined with purifier gas, or alternately a purifier gas that is introduced into the container interior and circulated through the container interior a single time or multiple times (e.g., recirculated). As the gas contacts the contaminant removal device, one or more contaminants in the gas are removed from the gas by the contaminant removal device and the gas that exits the contaminant removal device contains a reduced amount (concentration) of the one or more contaminants.

The purification system includes a control system that includes or is connected to one or more different types of sensors, including a sensor to detect and measure a concentration of one or more airborne molecular contaminants in a gas during a purification step, e.g., an “airborne molecular contaminant sensor” or “AMC sensor,” such as a volatile organic compound sensor (“VOC sensor”). Other sensors may measure temperature, pressure, or relative humidity of a gas that passes through the purification system, fluid flow through the container interior or the purification system, or the like. The control system receives input from the AMC sensor during a purification process and monitors the concentration level of one or more airborne molecular contaminants in a gas (gaseous atmosphere, purifier gas, etc.) that flows through the container interior during the purification process. The control system may compare a measured concentration of a specific airborne molecular contaminant to a desired maximum concentration of one or more airborne molecular contaminants in a gas, referred to as a “criteria concentration.”

Sensors of a control system measure and monitor one or more of: a concentration of an airborne molecular contaminant or concentrations of two or more different airborne molecular contaminants; temperature; relative humidity; or flow, etc., in cooperation with at least a computerized hardware processor with a memory device that is operatively connected to the processor. The memory device can store instructions to be executed at the processor, optionally in response to values measured at one or more sensors, including the AMC sensor. According to various example purification systems, a control system can include, as a computer processor, a microprocessor of any form, e.g., a process logic controller (PLC controller) embodied in an application-specific integrated circuit (ASIC), or the like.

In an example system, one or more sensors can be positioned relative to a substrate container at locations to measure a concentration of one or more AMC contaminants within a gas that passes through the purification system, as well as temperature, pressure, or relative humidity of the gas, or two or more of these. Sensors may be at a container interior, at an inlet of a contaminant removal device to measure a condition of a gas flowing into the contaminant removal device, at an outlet of the contaminant removal device to measure a condition of a gas flowing from the contaminant removal device, or at any other effective location. The process control system can receive one or more measured values from the sensors and use that information to control the timing or sequence of steps of a purification process.

Example substrate containers include a multi-sided container body (sometimes referred to as a “shell”) that defines a container interior that is adapted to contain and support one or more semiconductor substrates. The body includes an opening (“container opening” or “opening”) that allows access to the container interior on one side of the container body for transferring substrates into and out of the container interior. The container also includes a door that is adapted to selectively cover and un-cover the opening and form a seal over the opening between the container interior and an exterior of the container. A substrate container can typically also include at least one inlet port that is adapted to allow a gas, e.g., a “purge gas” or a purifier gas,” to be delivered to the container interior, as well as at least one (optional) outlet port that allows a gaseous atmosphere, a purge gas, or a purifier gas at the container interior to flow out of the interior and pass to an exterior, for example during a purge step or a purification step as described.

The substrate container is adapted to contain multiple semiconductor substrates (“substrates” for short, or “wafers”). A “substrate” may be any of a variety of different generally flat structures that are known to be of a type that is commonly contained or transported in a substrate container to allow safe and clean handling and transport of the substrate without causing damage or contamination of the substrate. Example substrates include semiconductor wafers, precursors thereof, derivatives thereof, and in-process versions of any of these, including in-process semiconductor wafers, in-process microelectronic devices, EUV (extreme ultraviolet light) reticles, panels, or other structures known to be held or transported in a substrate container as described, any of which may be referred to generically as a “wafer” or a “substrate.”

FIG. 1 shows a substrate container that can be used with a purification system as described. Substrate container 1 includes container body (e.g., “shell”) 2, front opening 4, interior 8, ports (inlets our outlets) 10 in the form of openings that pass through the bottom wall of shell 2, and slots 12 at opposite sidewalls to support multiple substrates. Slots 12 are adapted to engage and support edges of multiple substrates (not shown) as the substrates are held within interior 8. Substrate container 1 also includes door 6, which can be used to cover opening 4 to close and seal interior 8.

Substrate container 1 can be used for transporting, containing, or storing semiconductor wafers (substrates) that are being processed by a series of processing steps (i.e., wafers that are “in-process”), between steps of the series. Substrate container 1 can include a standard mechanical interface (SMIF) of a type known for use with semiconductor processing equipment. As illustrated at FIG. 1, container 1 is a front opening container, for example, a “front opening unified pod” or “FOUP.”

An example purification system in basic form can define a fluid path between a substrate container interior and a contaminant removal device that allows a gas to flow from the container interior to contact a contaminant removal device, and then optionally but not necessarily flow back into the container interior. As the gas contacts the contaminant removal device, one or more contaminants in the gas are removed from the gas by the contaminant removal device and the gas that exits the contaminant removal device contains a reduced amount (concentration) of the one or more contaminants. A concentration of one or more airborne molecular contaminants in the gas can be monitored as the gas circulates through the substrate container interior and the purification system, and the concentration can be compared to a criteria concentration.

In example methods, the gas may be a gaseous atmosphere contained in the closed substrate container during use, optionally while substrates are held at the container interior. The gaseous atmosphere may be circulated and re-circulated through the purification system without the addition of an additional purifier gas. As the gaseous atmosphere circulates through the container interior and the purification system, the concentration of one or more airborne molecular contaminants in the gaseous atmosphere can be monitored and compared to a criteria concentration.

According to other methods, the gas may be a purifier gas that is introduced into the container interior from a separate source, meaning a source that is outside of the container interior. The purifier gas may be introduced to the container interior from the separate source and may be passed through the container interior a single time or multiple times, e.g., recirculated through the container interior multiple times. As the gas is passes through the purification system, the concentration of one or more airborne molecular contaminants in the gas can be monitored and compared to a criteria concentration.

The purification system includes at least one airborne molecular contaminant sensor to detect and measure a concentration of one or more airborne molecular contaminants present in a gas that is contained in or that has passed through the container interior. The gas may pass through the container interior and purification system a single time and be continuously replaced within the substrate container interior with a continuous flow of the purifier gas. Alternately, the gas may be circulated multiple times (e.g., “re-circulated”) through the container interior. In either method, a concentration of one or more airborne molecular contaminants in the gas can be measured during a purification step and compared to a criteria concentration.

The sensor can be connected to or part of a control system that monitors the concentration of one or more airborne molecular contaminants in the gas during a purification process. Optional components of a purification system may include a flow control device to cause the gas to flow into and through the contaminant removal device, one or more sources of purifier gas, one or more flow conduits, flow control devices such as valves and flow meters, and additional sensors such as flow sensors, relative humidity sensors, temperature sensors, and the like, connected to or as part of the control system.

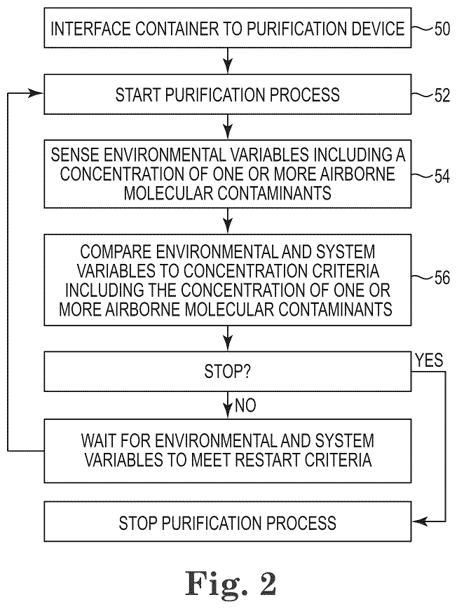

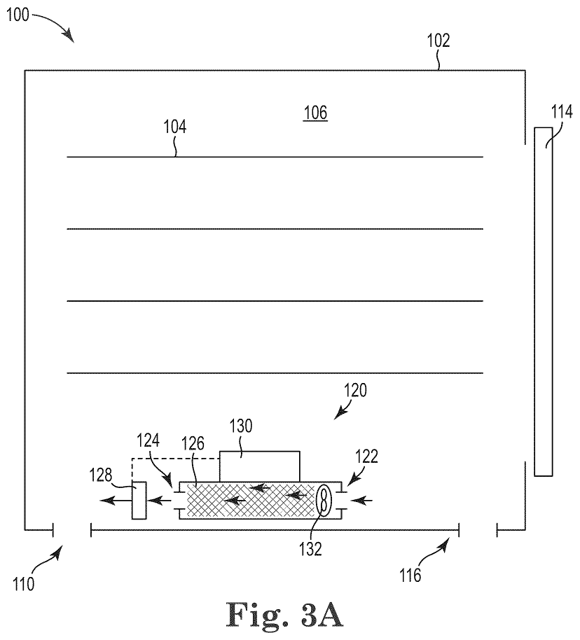

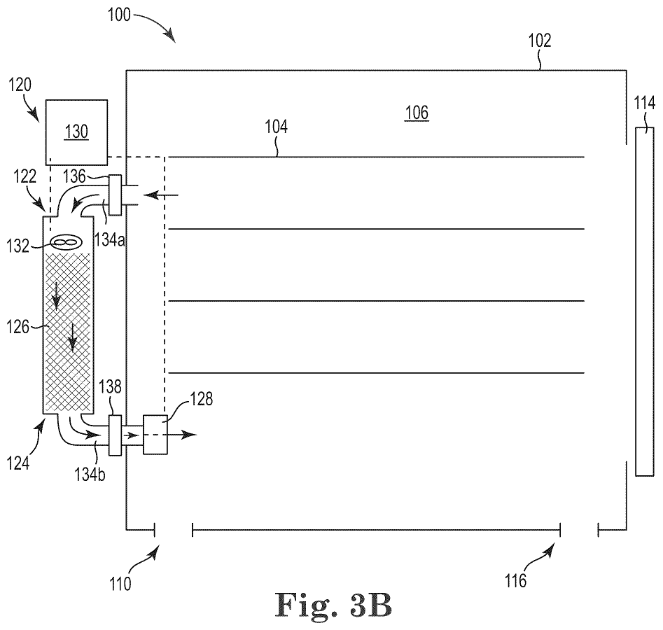

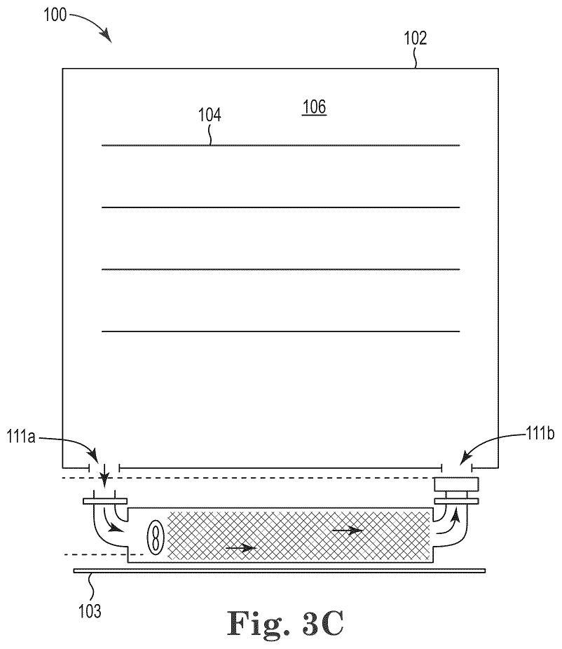

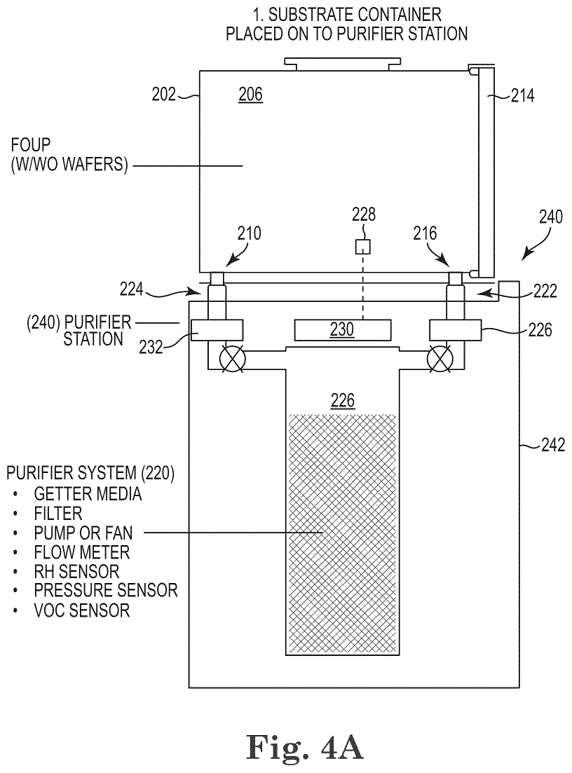

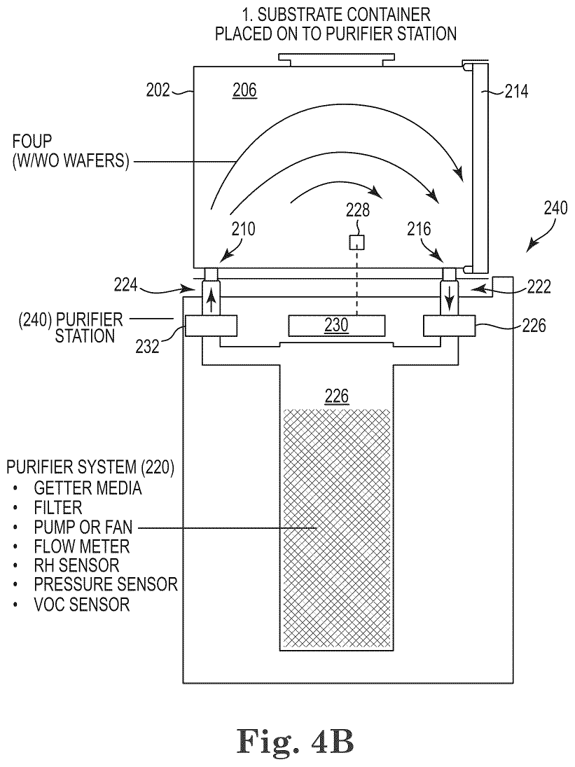

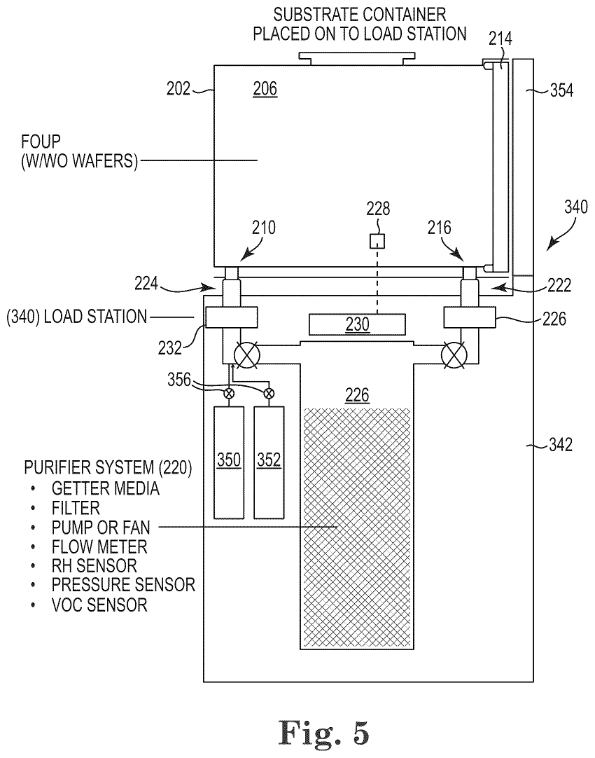

Example steps of a purification process are shown at FIG. 2. Initially, 50, a purification system (or “purification device”) is engaged with a substrate container and the purification device is connected to the substrate container interior. For some systems and methods, the purification system is located within the container interior, or within a container sidewall or top or bottom, or is attached to the container exterior (see FIGS. 3A and 3B). In these examples, the purification system may be permanently or removably engaged with the substrate container. In other systems and methods (see FIGS. 4A, 4B, and 5) the container can be removably engaged with the purification device by placing the container onto an apparatus (purifier station or load port) that includes the purification system, to engage the purification system with the container and connect the purification system to the container interior.

Some systems and methods will circulate a gaseous atmosphere that is contained within a substrate container between the interior and the purification system and will not combine the gaseous atmosphere with additional gas such as a purifier gas. Referring to FIG. 2, a purification process is started, 52, by causing a gaseous atmosphere enclosed in the container to flow through a contaminant removal device of the purification system. Environmental variables including a concentration of one or more airborne molecular contaminants in the gaseous atmosphere are measured, 54. This initial concentration can be compared to a criteria concentration, 56, such as a pre-determined (maximum) concentration of the one or more airborne molecular contaminants in the atmosphere. The gaseous atmosphere is circulated through the interior and through the purification system. The concentration of the one or more airborne molecular contaminants in the gaseous atmosphere is measured as the purification process proceeds, and may be measured continuously or periodically during a purification process. The purification process may be carried out as a single step or as a series of multiple steps or cycles with measurements of concentrations of airborne molecular contaminants being performed between each step or cycle. When a concentration of the one or more airborne molecular contaminants reaches a desired criteria concentration the purification process is complete. While these steps describe a method that circulates only the gaseous atmosphere through the container interior and the purification system, the method may optionally include combining the gaseous atmosphere with purifier gas from a separate source.

Other example systems and methods use a purifier gas in combination with or in place of a gaseous atmosphere present in a substrate container. Referring again to FIG. 2, a purification process is started, 52, by introducing a purifier gas from a separate source into the interior of an enclosed substrate container. The purifier gas can be combined with the gaseous atmosphere, and the gas (the combination of purifier gas and gaseous atmosphere) may be circulated through a closed system that includes the container interior and the purification device. Concentrations of one or more airborne molecular contaminants in the gas are measured, 54. The gas is circulated through the interior and through the purification system, optionally by being re-circulated. When a concentration of one or more airborne molecular contaminants reaches a desired criteria concentration the purification process is complete.

According to any of the described examples of purification processes and their specific steps, a purification process may include a step of heating a gas (e.g., a purifier gas) before the gas enters the substrate container. A heated gas may be more effective in removing contaminants from a container interior. For example, a purifier gas (e.g., clean dry nitrogen or moisture-free clean dry air, or the like) at an elevated temperature (e.g., at least 50, 70, 80, 90, or 100 degrees Celsius or higher) may be effective to energize and volatilize contaminants at surfaces of a substrate container interior, e.g., accumulated at interior surfaces or adsorbed by a material of an interior surface. When a gas is heated before being passed into the substrate interior, the gas should also, preferably, be cooled before the gas contacts a contaminant removal device that includes adsorbent. The cooling step may be performed by any effective cooling method, and the gas can be cooled to a temperature that allows for the adsorbent to effectively adsorb airborne molecular contaminants that are contained in the gas to remove the contaminants from the gas, e.g., to a temperature that is below 50, 40, or 30 degrees Celsius.

According to certain example purification systems, a purification system may have one or more components of the system located at an interior of a substrate container, optionally incorporated (fixedly-assembled) into the structure of the substrate container or a substrate container housing. The purification system may be incorporated into the substrate container and located at the interior space of the substrate container at a side, bottom, or top of the interior; or may alternately be incorporated into a sidewall (e.g., a top, bottom, or a back or front or side sidewall of the container; or may be incorporated into the container at a location external to the container but connected by flow channels to the container interior.

As illustrated at FIG. 3A, substrate container 102 and purification system 120 are assembled into a combined substrate container-purification system 100. System 100 includes substrate container 102, which contains multiple substrates 104 held within interior 106. Door 114 covers an opening of the container housing and is illustrated schematically as being placed in a closed position. Container 102 includes inlet 110 to allow gas (e.g., purge gas or purifier gas) to flow into interior 106, and outlet 116 to allow gaseous atmosphere or purge gas or purifier gas to flow from interior 106 to an exterior of container 102. Substrates (e.g., wafers) 104 are optional because a purification step may be performed on container 102 either while the container holds one or more substrates 104 at interior 106 or while the container does not hold any substrates at the interior.

Purification system 120 includes contaminant removal device 126, which may be an adsorbent, oxidizer, or another type of contaminant removal device. Device 126 includes inlet 122 through which gas from interior 106 enters device 126, and outlet 124 through which the gas exits device 126 after contacting contaminant removal device 126. A flow control device (e.g., pump or fan) 132 can be included as part of purification system 120 to cause the gas contained at interior 106 to flow into inlet 122, flow past and contact contaminant removal device 126, flow through outlet 124, and return to interior 106 (see arrows). Purification system 120 also includes AMC sensor 128, which is part of or is connected electronically to control system 130. AMC sensor 128 can detect and measure a concentration of one or more airborne molecular contaminants present in an atmosphere of interior 106 before and during a purification step. Optionally, a heater (not shown) can heat effluent gas leaving contaminant removal device 126, and a cooler (or “cooling device,” not shown) can cool gas that enters contaminant removal device 126.

In use to perform a step of purifying a container 102, flow control device 132 causes the gas contained at interior 106 to flow through inlet 122, contact contaminant removal device 126, flow through outlet 124, and return to interior 106. When the gas contacts contaminant removal device 126, airborne molecular contaminants that are present in the gas are removed from the gas and are sequestered and contained by contaminant removal device 126.

During an example purification step, the gaseous atmosphere) contained in interior 106 is continuously circulated, i.e., “recirculated,” for a period of time through purification system 120 without adding or removing an amount of gas to or from the volume of gaseous atmosphere originally enclosed within interior 106 of substrate container 102. During the purification step, AMC sensor 128 monitors a concentration of one or more airborne molecular contaminants present in the gas. As illustrated, sensor 128 is located to contact an effluent of contaminant removal device 126, but sensor 128 may be located at any location that allows sensor 128 to measure a concentration of airborne molecular contaminant within the gas. As the purification step is performed the concentration of one or more airborne molecular contaminants in the gas will be reduced. When a measured concentration of one or more contaminants in the gas reaches a desired low concentration, i.e., a pre-determined concentration of one or more airborne molecular contaminants (a.k.a. a “criteria concentration”), the purification step can be considered to be complete. An AMC sensor (not illustrated) may alternately or additionally be located at inlet 122 to measure a concentration of contaminant in the gas before purification, and that concentration before purification can be compared to the criteria concentration. Sensor 128 at the outlet may also be useful to determine whether a contaminant removal device 126 in the form of an adsorbent has reached capacity, e.g., whether the ability of the adsorbent to remove contaminant has been depleted.

In the example of FIG. 3A, purifier device 120 is located within interior 106 of container 102. Alternately, purifier device 120 or one or more components thereof may be located in a housing structure of container 102 such as a topwall, a bottom wall, or a sidewall, not within the space of interior 106 but still being incorporated into the structure of container 102.

According to another example of a purification system as shown at FIG. 3B, one or more components of purification system 120 may be located external to substrate container 102 and may be connected to interior 106 of container 102 using fluid conduits 134a and 134b that connect interior 106 and inlet 124 and 122, respectively. As specifically illustrated at FIG. 3B, certain components of purification system 120 are located external to container 102 and connected to interior 106 using fluid conduits 134a and 134b that pass through a container sidewall. As illustrated, conduits 134a and 134b pass through a sidewall of container 102 but other examples of a purification system may include conduits that pass through a top of the container, a bottom of a container, or a door (e.g., 114) of the container. Optionally, the conduits 134a and 134b may allow for contaminant removal device 126 to be selectively connected and disconnected from container 102 and attached and detached as desired, e.g., device 126 may be removably attached to container 102. According to yet a different system, these components may be incorporated into container 102 within a housing of container 102, e.g., within a topwall, a bottom wall, or a sidewall, while not being located within the space of interior 106. Optional heater 138 can heat effluent gas leaving contaminant removal device 126, and optional cooler (“cooling device”) 136 can reduce a temperature of gas that enters contaminant removal device 126.

According to another example of a purification system as shown at FIG. 3C, one or more components of purification system 120 may be located between the external to substrate container 102 and a bottom plate 103 and may be connected to interior 106 of container 102 using conduits 134a and 134b that connect interior 106 and inlet 124 and 122, respectively. As specifically illustrated at FIG. 3C, certain components of purification system 120 are located between the external to container 102 and a bottom plate 103 and connected to interior 106 using conduits 134a and 134b that pass through container ports 111a and 111b. As illustrated, conduits 134a and 134b pass through a bottom wall of container 102 at ports 111a and 111b at a front side of the container 102 but other examples of a purification system may include ports at a back side of the container. Optionally, the conduits 134a and 134b may allow for contaminant removal device 126 to be selectively connected and disconnected from container 102 and attached and detached as desired, e.g., device 126 may be removably attached to container 102. Optional heater 138 can heat effluent gas leaving contaminant removal device 126, and optional cooler (“cooling device”) 136 can reduce a temperature of gas that enters contaminant removal device 126.

A different example of a purification system useful in combination with a container is shown at FIG. 4A. According to this example, container 202 is supported by purifier station 240, which includes a purifier station body 242 that physically supports container 202 at an upper surface that engages a bottom surface of container 202. Substrate container 202 contains interior 206, which as illustrated does not contain substrates but alternately may contain substrates. Door 214 covers an opening of the container housing and is illustrated as being placed in a closed position. Container 202 includes inlet 210 to allow gas to flow into interior 206, and outlet 216 to allow gas to flow from interior 206 to an exterior of container 202. Substrates (e.g., wafers) are optional because a purification step may be performed on container 202 either while the container holds one or more substrates at interior 206 or while the container does not hold any substrates at the interior.

Purifier station body 242 contains purification (or “purifier”) system 220 that includes a contaminant removal device (e.g., adsorbent, “getter media,” oxidizer) 226, a filter (which is optional) for removing particle contaminants, a flow control device such as a pump or a fan, an AMC sensor (e.g., a “volatile organic compound sensor” or “VOC sensor”), and as illustrated also includes a relative humidity sensor and a pressure sensor. Control system 230 communicates electronically with components of purification system 220 and container 202, such as sensors and flow control devices to control a purification process.

Container 202 includes container inlet 210 which is connected to outlet 224 of purifier station 240, and container outlet 216 which communicates with inlet 222 of purifier station 240. During use, gas from interior 206 enters purification system 220 through inlet 222, passes through contaminant removal device 226, then passes from outlet 224 to return to interior 206 of container 202. A flow control device such as a fan or pump can produce a continuous flow of the gas through the container and purification system 220. Contaminant removal device 226 may include an adsorbent or oxidizer that is effective to remove airborne molecular contaminants from the gas and may also include a filter to remove particle contamination. Purification system 220 may also include one or more sensors 228, which include at least a sensor to detect and measure a concentration of one or more airborne molecular contaminants in the gas during a purification step, and optionally also includes one or more sensors to measure temperature, relative humidity, and pressure at locations within interior 206 or purification system 220. Sensors 228 are part of or are connected electronically to control system 230. Optionally, but not illustrated, purification system 220 can include one or more sources of purifier gas such as dry nitrogen or clean dry air that can be flowed into interior 206 during a purification step. Optional heater 232 can heat effluent gas leaving contaminant removal device 226, and optional cooler 226 can cool (reduce a temperature of) gas that enters contaminant removal device 126.

In use, as shown at FIG. 4B, a step of purifying interior 206 of container 202 can be performed by causing the gas contained at interior 206 to flow through inlet 222 of the purification system to contact contaminant removal device 226 and then return to interior 206 through outlet 224 of the purification system. When the gas contacts contaminant removal device 226, airborne molecular contaminants that are present in the gas are removed from the gas and are sequestered and contained by contaminant removal device 226. The gas may be cycled (re-circulated) through interior 206 and purification system 220 for an amount of time (or based on flow volume) that is sufficient to reduce a level of contaminants (e.g., one or more airborne molecular contaminants) in the gas to a desired concentration. During a purification cycle the concentration of the one or more contaminants will be reduced to gradually reduced levels. In example methods, a purification step can be considered to be complete and may be ended when a measured concentration of one or more airborne molecular contaminants reaches a desired low concentration, referred to as a “criteria concentration.”

Yet another example of a purification system useful for a step of purifying a substrate container can be a purification system that is incorporated into a load port apparatus as shown at FIG. 5. According to this example, a container 202 is supported by load port 340, which includes a load port body 342 that physically supports container 202 at an upper surface that engages a bottom surface of container 302.

Load port 340 is comparable to purification station 240 and includes features thereof, with the additional structures of one or more sources of purifier gas 350, 352, or both; an “outer” door 354; and control system 230 that communicates with the substrate container and purification system to control a one or more flows of purifier gas into and through the container interior and purification system. Load port 340 can be a component of or can be adapted to engage any of a variety of semiconductor processing apparatuses to allow substrates to be transferred from a substrate container to the semiconductor processing apparatus. The load port contains a door 354 that can be selectively opened and closed and that is situated between the semiconductor processing apparatus (not shown) and door 214 of the substrate container (referred to as the “inner door”). Load port 340 is adapted to support container 202 at a location adjacent to the semiconductor processing apparatus (not shown) to allow substrates held at the substrate container interior to be transferred between the substrate container and the processing apparatus under clean conditions.

Purifier gas sources 350 and 352 may include a source of any useful purifier gas such as nitrogen gas (dry nitrogen gas) or clean dry air (e.g., “XCDA”). Alternately, one or more purifier gas sources may be external to load port 340 and one or more purifier gases may be supplied from infrastructure of a fabrication facility. During use, the purification system of load port 340 can be used in manner and with steps as described, including as described with respect to purification system 220 of FIGS. 4A and 4B. During a purification step one or more of the purifier gases may be caused to flow into interior 206. The purifier gas may displace the gaseous atmosphere and subsequently be continuously flowed through interior 206 a single time or multiple times (re-circulated) while a concentration of one or more airborne molecular contaminants in the purifier gas is measured, such as while the gas exits interior 206 (the “effluent purifier gas”). Alternately, the purifier gas may be added to the gaseous atmosphere and the mixture of gases may be circulated multiple times (e.g., “re-circulated”) through interior 206 and purification system 220 while a concentration of one or more airborne molecular contaminants in the combination of gases is measured. Optional heater 232 can heat effluent gas leaving contaminant removal device 226, and optional cooler (“cooling device”) 226 can cool (reduce a temperature of) gas that enters contaminant removal device 126.

One or more flow meters control a flow of the purifier gas from source 350, 354 to inlet 210 and into interior 206. When the gas contacts contaminant removal device 226, airborne molecular contaminants that are present in the gas are removed from the gas and are sequestered and contained by contaminant removal device 226. The gas may be cycled (re-circulated) through interior 206 and purification system 220 for an amount of time (or based on flow volume) that is sufficient to reduce a level of contaminants in the atmosphere to a desired concentration. During a purification cycle, the concentration of the one or more contaminants will be reduced to gradually reduced levels. In example methods, a purification step can be considered to be complete and may be ended when a measured concentration of one or more airborne molecular contaminants reaches a desired low concentration, referred to as a “criteria concentration.”

### Aspects

Aspect 1. A purification system for purifying a substrate container, the substrate container comprising: a container body comprising an opening, a door adapted to cover the opening, an interior defined by the container body, a gas within the interior, the purification system comprising: a contaminant removal device in fluid communication with the interior, a control system adapted to measure a concentration of airborne molecular contaminant in the gas.

Aspect 2. The system of Aspect 1 further comprising a sensor in fluid communication with the interior, adapted to detect airborne molecular contaminant in the gas.

Aspect 3. The system of Aspect 1 wherein the control system is adapted to compare the concentration to a criteria concentration.

Aspect 4. The system of Aspect 1 wherein the contaminant is a volatile organic compound and the contaminant removal device is selected from an adsorbent and an oxidizer.

Aspect 5. The system of Aspect 1 wherein the airborne molecular contaminant comprises: an acid molecule, a base molecule, isopropyl alcohol, acetone, ammonia, sulfur dioxide, ethyl acetate, hydrogen fluoride, methyl-ethyl ketone, propylene glycol monomethyl ether, propylene glycol methyl ether acetate, toluene, or a combination thereof.

Aspect 6. The system of Aspect 1 wherein the airborne molecular contaminant comprises isopropyl alcohol, acetone, or both, and the contaminant removal device is a catalytic oxidizer.

Aspect 7. The system of Aspect 1 wherein airborne molecular contaminant comprises: monomer, dimer, oligomer, plasticizer, organic solvent, metal ion, or a combination of two or more of these.

Aspect 8. The system of Aspect 1 wherein the contaminant removal device comprises activated carbon, treated activated carbon, alumina, a metal organic framework (MOF), a zeolite, an ion exchange resin, a silica, or a molecular sieve.

Aspect 9. The system of Aspect 1 wherein the contaminant removal device comprises a polymer membrane, a mixed matrix membrane, a graphene membrane, or a graphene oxide membrane.

Aspect 10. The system of Aspect 1 wherein the contaminant removal device is located at the interior of the container.

Aspect 11. The system of Aspect 1 wherein the contaminant removal device is located at the exterior of the container.

Aspect 12. The system of Aspect 1 wherein the contaminant removal device is located within a top, a bottom, and/or a sidewall of the container body.

Aspect 13. The system of Aspect 1 wherein the contaminant removal device is a component of a purifier station.

Aspect 14. The system of Aspect 1 wherein the contaminant removal device is a component of a load station.

Aspect 15. The system of Aspect 13 wherein the purifier station or the load station includes one or more sources of purifier gas.

Aspect 16. The system of Aspect 1 comprising a flow control device adapted to cause the gas to flow from the interior to the contaminant removal device.

Aspect 17. The system of Aspect 1 further comprising a heater to heat gas flowing into the interior.

Aspect 18. The system of Aspect 1 comprising a cooling device to reduce a temperature of gas entering the contaminant removal device.

Aspect 19. A method of purifying a substrate container, the method comprising: in a substrate container comprising: a container body comprising an opening, a door adapted to cover the opening, an interior defined by the container body, a gas within the interior, causing the gas to contact a contaminant removal device to remove an airborne molecular contaminant from the gas.

Aspect 20. The method of Aspect 19 further comprising: measuring a concentration of the airborne molecular contaminant in the gas, and comparing the concentration of airborne molecular contaminant in the gas to a predetermined criteria concentration.

Aspect 21. The method of Aspect 19 wherein the contaminant is a volatile organic compound and the contaminant removal device is selected from an adsorbent and an oxidizer.

Aspect 22. The method of Aspect 19 wherein the contaminant removal device comprises activated carbon, treated activated carbon, alumina, a metal organic framework (MOF), a zeolite, an ion exchange resin, a silica, or a molecular sieve.

Aspect 23. The system of Aspect 19 wherein the contaminant removal device comprises a polymer membrane, a mixed matrix membrane, a graphene membrane, or a graphene oxide membrane.

Aspect 24. The method of Aspect 19 wherein the airborne molecular contaminant comprises: an acid molecule, a base molecule, isopropyl alcohol, acetone, ammonia, sulfur dioxide, ethyl acetate, hydrogen fluoride, methyl-ethyl ketone, propylene glycol monomethyl ether, propylene glycol methyl ether acetate, toluene, or a combination thereof.

Aspect 25. The method of Aspect 19 wherein the airborne molecular contaminant comprises isopropyl alcohol, acetone, or both, and the contaminant removal device is a catalytic oxidizer.

Aspect 26. The method of Aspect 19 wherein the airborne molecular contaminant comprises: monomer, dimer, oligomer, plasticizer, organic solvent, metal ion, or a combination of two or more of these.

Aspect 27. The method of Aspect 19 wherein the criteria concentration is less than 5 parts per billion of one or more of the airborne molecular contaminants.

Aspect 29. The method of Aspect 19 comprising flowing purifier gas into the interior.

Aspect 30. The method of Aspect 19 wherein one or more substrates are located in the interior.

Aspect 31. The method of Aspect 19 wherein the container does not contain a substrate.

Aspect 32. The method of Aspect 19 comprising flowing the gas from the interior, heating the gas, and flowing the gas through the contaminant removal device.

Aspect 33. The method of Aspect 32 comprising cooling the gas after it leaves the contaminant removal device.

Aspect 34. A purification step for purifying a substrate container comprising: stopping the purification step at a predetermined concentration of an airborne molecular contaminant.

Aspect 35. The purification step of Aspect 34 wherein: the airborne molecular contaminant comprises: an acid molecule, a base molecule, isopropyl alcohol, acetone, ammonia, sulfur dioxide, ethyl acetate, hydrogen fluoride, methyl-ethyl ketone, propylene glycol monomethyl ether, propylene glycol methyl ether acetate, toluene, or a combination thereof, and the stopping criteria concentration is less than 5 parts per billion of one or more of the airborne molecular contaminants.

Aspect 36. The purification step of Aspect 34 wherein the airborne molecular contaminant comprises: monomer, dimer, oligomer, plasticizer, organic solvent, metal ion, or a combination of two or more of these, and the criteria concentration is less than 5 parts per billion of one or more of the airborne molecular contaminants.

Aspect 37. The purification step of Aspect 34 wherein one or more substrates are located at the interior.

Aspect 38. The purification step of Aspect 34 wherein the container does not contain a substrate.

Aspect 39. A substrate container comprising a container body and a purification system, the substrate container comprising: a container body comprising: an opening, a door adapted to cover the opening, an interior defined by the container body, a gas within the interior, and a purification system comprising: a contaminant removal device in fluid communication with the interior, and a control system adapted to measure a concentration of airborne molecular contaminant in the gas.

Aspect 40. The substrate container of Aspect 39 further comprising a sensor in fluid communication with the interior, adapted to detect airborne molecular contaminant in the gas.

Aspect 41. The substrate container of Aspect 39 wherein the airborne molecular contaminant is a volatile organic compound and the contaminant removal device is selected from an adsorbent and an oxidizer.

Aspect 42. The substrate container of Aspect 39 wherein the airborne molecular

contaminant comprises: an acid molecule, a base molecule, isopropyl alcohol, acetone, ammonia, sulfur dioxide, ethyl acetate, hydrogen fluoride, methyl-ethyl ketone, propylene glycol monomethyl ether, propylene glycol methyl ether acetate, toluene, or a combination thereof.

Aspect 43. The substrate container of Aspect 39 wherein the airborne molecular contaminant comprises isopropyl alcohol, acetone, or both, and the contaminant removal device is a catalytic oxidizer.

Aspect 44. The substrate container of Aspect 39 wherein airborne molecular contaminant comprises: monomer, dimer, oligomer, plasticizer, organic solvent, metal ion, or a combination of two or more of these.

Aspect 45. The substrate container of Aspect 39 wherein the contaminant removal device comprises activated carbon, treated activated carbon, alumina, a metal organic framework (MOF), a zeolite, an ion exchange resin, a silica, or a molecular sieve.

Aspect 46. The substrate container of Aspect 39, wherein the contaminant removal device is located at the interior of the container.

Aspect 47. The substrate container of Aspect 39, wherein the contaminant removal device is located within a top, bottom, or sidewall of the container body.

Aspect 48. The substrate container of Aspect 39, wherein the contaminant removal device is located at the exterior of the container.

1. A purification system for purifying a substrate container, the substrate container comprising:
a container body comprising an opening,
a door adapted to cover the opening,
an interior defined by the container body,
a gas within the interior,
the purification system comprising:
a contaminant removal device in fluid communication with the interior,
a control system adapted to measure a concentration of airborne molecular contaminant in the gas.

2. The system of claim 1 further comprising a sensor in fluid communication with the interior, adapted to detect airborne molecular contaminant in the gas.

3. The system of claim 1 wherein the control system is adapted to compare the concentration to a criteria concentration.

4. The system of claim 1 wherein the contaminant is a volatile organic compound and the contaminant removal device is selected from an adsorbent and an oxidizer.

5. The system of claim 1 wherein the airborne molecular contaminant comprises: an acid molecule, a base molecule, isopropyl alcohol, acetone, ammonia, sulfur dioxide, ethyl acetate, hydrogen fluoride, methyl-ethyl ketone, propylene glycol monomethyl ether, propylene glycol methyl ether acetate, toluene, or a combination thereof.

6. The system of claim 1 wherein airborne molecular contaminant comprises: monomer, dimer, oligomer, plasticizer, organic solvent, metal ion, or a combination of two or more of these.

7. The system of claim 1 wherein the contaminant removal device comprises activated carbon, treated activated carbon, alumina, a metal organic framework (MOF), a zeolite, an ion exchange resin, a silica, or a molecular sieve.

8. The system of claim 1 wherein the contaminant removal device comprises a polymer membrane, a mixed matrix membrane, a graphene membrane, or a graphene oxide membrane.

9. The system of claim 1 wherein the contaminant removal device is located at the interior of the container.

10. The system of claim 1 wherein the contaminant removal device is located at the exterior of the container.

11. The system of claim 1 wherein the contaminant removal device is a component of a purifier station.

12. The system of claim 1 wherein the contaminant removal device is a component of a load station.

13. The system of claim 1 further comprising a flow control device adapted to cause the gas to flow from the interior to the contaminant removal device.

14. The system of claim 1 further comprising a heater to heat gas flowing into the interior.

15. The system of claim 1 further comprising a cooling device to reduce a temperature of gas entering the contaminant removal device.

16. A substrate container comprising a container body and a purification system, the substrate container comprising:
a container body comprising:
an opening,
a door adapted to cover the opening,
an interior defined by the container body,
a gas within the interior, and
a purification system comprising:
a contaminant removal device in fluid communication with the interior, and
a control system adapted to measure a concentration of airborne molecular contaminant in the gas.

17. The substrate container of claim 16 further comprising a sensor in fluid communication with the interior, adapted to detect airborne molecular contaminant in the gas.

18. The substrate container of claim 16 wherein the airborne molecular contaminant is a volatile organic compound and the contaminant removal device is selected from an adsorbent and an oxidizer.

19. The substrate container of claim 16 wherein the airborne molecular contaminant comprises: an acid molecule, a base molecule, isopropyl alcohol, acetone, ammonia, sulfur dioxide, ethyl acetate, hydrogen fluoride, methyl-ethyl ketone, propylene glycol monomethyl ether, propylene glycol methyl ether acetate, toluene, or a combination thereof.

20. The substrate container of claim 16 wherein airborne molecular contaminant comprises: monomer, dimer, oligomer, plasticizer, organic solvent, metal ion, or a combination of two or more of these.

21. The substrate container of claim 16 wherein the contaminant removal device comprises activated carbon, treated activated carbon, alumina, a metal organic framework (MOF), a zeolite, an ion exchange resin, a silica, or a molecular sieve.
